(19) United States
(12) Patent Application Publication
(10) Pub. No.: US 2008/0233489 A1
(43) Pub. Date: Sep. 25, 2008

(54) Method to form a pattern of functional material on a substrate using a stamp having a surface modifying material

(76) Inventors: Graciela Beatriz Blanchet, Wilmington (DE); Hee Hyun Lee, Wilmington (DE); Gary Delmar Jaycox, West Chester, PA (US)

Correspondence Address: E I DU PONT DE NEMOURS AND COMPANY;LEGAL PATENT RECORDS CENTER, BARLEY MILL PLAZA 25/1122B, 4417 LANCASTER PIKE, WILMINGTON, DE, 19805, US

(21) Appl. No.: 11/726,770

(22) Filed: Mar. 22, 2007

(51) Int. Cl. G03F 1/06

(52) U.S. Cl. 430/5

(57) ABSTRACT

The invention provides a method to form a pattern of functional material on a substrate. The method uses an elastomeric stamp having a relief structure with a raised surface and having a modulus of elasticity of at least 10 MegaPascal. A surface modifying material is applied to the relief structure and forms a layer at least on the raised surface. A composition of the functional material and a liquid is applied to the layer of the surface modifying material on the relief structure and the liquid is removed to form a film. The elastomeric stamp transfers the functional material from the raised surface to the substrate to form a pattern of the functional material on the substrate. The method is suitable for the fabrication of microcircuitry for electronic devices and components.

### BACKGROUND OF THE INVENTION

1. Field of the Invention

This invention pertains to a method for forming a pattern of functional material on a substrate, and in particular, the method uses an elastomeric stamp having a raised surface to form the pattern on the substrate for use in microfabrication of components and devices.

2. Description of Related Art

Nearly all electronic and optical devices require patterning. Microelectronic devices have been prepared by photolithographic processes to form the necessary patterns. According to this technique a thin film of conducting, insulating or semiconducting material is deposited on a substrate and a negative or positive photoresist is coated onto the exposed surface of the material. The resist is then irradiated in a predetermined pattern, and irradiated or non-irradiated portions of the resist are washed from the surface to produce a predetermined pattern of resist on the surface. To form a pattern of a conducting metal material, the metal material that is not covered by the predetermined resist pattern is then etched or removed. The resist pattern is then removed to obtain the pattern of metal material. Photolithography, however, is a complex, multi-step process that is too costly for the printing of plastic electronics.

Contact printing is a flexible, non-lithographic method for forming patterned materials. Contact printing potentially provides a significant advance over conventional photolithographic techniques since the contact printing can form relatively high resolution patterns on plastic electronics for electronic parts assembly. Microcontact printing can be characterized as a high-resolution technique that enables patterns of micron dimensions to be imparted onto a substrate surface. Microcontact printing is also more economical than photolithography systems since it is procedurally less complex, ultimately not requiring spin coating equipment or a sequential development step. In addition, microcontact printing potentially lends itself to reel-to-reel electronic parts assembly operations that allows for high throughput production than other techniques, such as photolithography and e-beam lithography (which is a conventional technique employed where resolution on the order of 10 s of nanometer is desired). Multiple images can be printed from a single stamp in reel-to-reel assembly operations using microcontact printing.

Contact printing is a possible replacement to photolithography in the fabrication of microelectronic devices, such as radio frequency tags (RFID), sensors, and memory and backpanel displays. The capability of microcontact printing to transfer a self-assembled monolayer (SAM) forming molecular species to a substrate has also found application in patterned electroless deposition of metals. SAM printing is capable of creating high resolution patterns, but is generally limited to forming metal patterns of gold or silver with thiol chemistry. Although there are variations, in SAM printing a positive relief pattern provided on an elastomeric stamp is inked onto a substrate. The relief pattern of the elastomeric stamp, which is typically made of polydimethylsiloxane (PDMS), is inked with a thiol material. Typically the thiol material is an alkane thiol material. The substrate is blanket-coated with a thin metal film of gold or silver, and then the gold-coated substrate is contacted with the stamp. Upon contact of the relief pattern of the stamp with the metal film, a monolayer of the thiol material having the desired microcircuit pattern is transferred to the metal film. Alkane thiols form an ordered monolayer on metal by a self-assembly process, which results in the SAM being tightly packed and well adhered to the metal. As such, the SAM acts as an etch resist when the inked substrate is then immersed in a metal etching solution and all but the SAM-protected metal areas are etched away to the underlying substrate. The SAM is then stripped away leaving the metal in the desired pattern.

A method of transferring a material to a substrate, particularly for light emitting devices, is disclosed by Coe-Sullivan et al. in WO 2006/047215. The method includes selectively depositing the material on a surface of a stamp applicator and contacting the surface of the stamp applicator to the substrate. The stamp applicator may be textured, that is have a surface with a pattern of elevations and depressions, or may be featureless, that is, having no elevations or depressions. The material is a nanomaterial ink that includes semiconductor nanocrystals. Direct contact printing of the material on the substrate eliminates the steps associated with SAM printing in which excess material that does not form the desired microcircuitry pattern from the substrate is etched away or removed. The stamp applicator can be made of an elastomeric material such as polydimethylsiloxane (PDMS).

Although it has been shown that 20 nm features can be achieved when printing via thiol chemistry, it is limited to a few metals and is not compatible with reel-to-reel processes. In contrast, it is difficult to form patterns of functional material with resolution on the order of 50 micron or less, and particularly 1 to 5 micron, by direct relief printing of the functional material.

A problem sometimes arises with microcontact printing in that the material to be printed does not spread or wet on the relief surface of the elastomeric stamp. If the material to be printed does not coat or sufficiently coat the relief surface the stamp, the material does not uniformly transfer to the substrate when printed, rendering an incomplete pattern of the material on the substrate.

So it is desirable to provide a method for forming a pattern of a functional material onto a substrate. It is desirable for the method to directly form the pattern of the functional material on the substrate. It is particularly desirable to directly form the pattern of a conductive material on the substrate and thereby eliminate the intermediate etching steps for removing the conductive material not forming the pattern. It is also desirable for such method to have the ease of microcontact printing with an elastomeric stamp and capable of reproducing resolution of 50 micron or less, and particularly on the order of 1 to 5 micron, but not be limited to printing onto metals. It is also desirable for such a method to provide complete coverage or improved coverage of the material being printed on the relief surface of the elastomeric stamp, in order for uniform transfer of the material forming the pattern on the substrate.

### SUMMARY OF THE INVENTION

The present invention provides a method to form a pattern of functional material on a substrate. The method includes providing an elastomeric stamp having a relief structure with a raised surface, the stamp having a modulus of elasticity of at least 10 MegaPascal. The method includes applying a first composition comprising a surface modifying material to the relief structure that provides uniform application of a second material; applying the second composition comprising the functional material and a liquid onto the surface modifying material, and removing the liquid from the composition on the relief structure sufficiently to form a film of the functional material on at least the raised surface. The functional material transfers from the raised surface to form the pattern on the substrate.

### BRIEF DESCRIPTION OF THE DRAWINGS

FIG. 1 is a sectional elevation view of a master having a relief structure that forms a pattern of a microcircuit or other functional electronic pathway.

FIG. 2 is a sectional elevation view of one embodiment of a printing form precursor having a layer of an elastomeric material between a support and the master, the elastomeric layer being exposed to actinic radiation.

FIG. 3 is a sectional elevation view of a stamp formed from the printing form precursor separating from the master. The stamp has a relief structure corresponding to the relief pattern of the master, and in particular, the relief structure of the stamp includes a pattern of at least a raised surface and a recessed surface that is the opposite of the relief of the master.

FIG. 4 is a sectional elevation view of the elastomeric stamp residing on a platform of a spin coater as one embodiment of applying a surface modifying material to the relief structure of the stamp.

FIG. 5 is a sectional elevation view of the elastomeric stamp residing on a platform of a spin coater as one embodiment of applying a functional material to the layer of the surface modifying material on the relief structure of the stamp.

FIG. 6 is a sectional elevation view of the elastomeric stamp having the layer of the surface modifying material and the layer of the functional material where the layer of functional material is contacting a substrate.

FIG. 7 is a sectional elevation view of the elastomeric stamp separating from the substrate, and transferring the functional material to the substrate to form a pattern of the functional material.

### DETAILED DESCRIPTION OF THE PREFERRED EMBODIMENT(S)

The present invention provides a method to form a pattern of functional material on a substrate for use in devices and components in a variety of applications, including but not limited to, electronic, optical, sensory, and diagnostic applications. The method is applicable to the pattern formation of a variety of active materials and inactive materials as the functional material. The method is not limited to the application by elastomeric stamps of thiol materials as a masking material. The method is capable of directly forming the pattern of the functional material onto a variety of substrates over large areas with line resolution of less than 50 micron, and thus is particularly capable of forming microcircuitry. Fine line resolution of 1 to 5 micron can even be attained by the present method. The method employs the ease of printing with an elastomeric stamp having a relief structure to transfer the functional material, without sagging or substantial sagging of the stamp and undesired transfer of material to the substrate, particularly when compared to stamps made of PDMS. The method provides improved wetting or spread of the functional material on the elastomeric stamp, which provides more uniform coverage or distribution of the functional material on the relief structure of the stamp. The method may also provide improved patternwise transfer or printing of the pattern of functional material on the substrate. The present method enables printing of a variety of functional materials over relatively large areas with micron resolution. The method also enables printing of sequential overlays without hampering the functionality of one or more underlying layers. The method can be adapted to high-speed production processes particularly for the fabrication of electronic devices and components, such as reel-to-reel processes.

A stamp is provided for patterning a substrate. The stamp includes a relief structure with a raised surface. Typically the relief structure will include a plurality of raised surfaces and a plurality of recessed surfaces. The relief structure of the stamp forms a pattern of raised surfaces for printing a functional material on a substrate. The pattern of the functional material on the substrate provides an operative function to a component or device. The raised surfaces of the relief structure of the elastomeric stamp represent the pattern of the functional material that will ultimately be formed on the substrate by the present method, and the recessed surfaces represent the background or featureless areas on the substrate. The present method uses an elastomeric stamp having a modulus of elasticity of at least 10 MegaPascal (Mpa), which provides the capability to form features of various functional materials on the substrate of less than 50 micron resolution. The method is capable of forming line resolution less than 30 micron, to as fine as 1 to 5 micron. In some embodiments where the functional material is, for example, a semiconductor or a dielectric material, resolution of less than 50 micron is acceptable since this resolution meets the requirements in electronic devices and components. In some embodiments where the functional material is, for example, a conductive material, the method is capable of forming features of 1 to 5 micron. The present method directly prints a pattern of the functional material on the substrate, and thus eliminates the intermediate etching steps associated with standard microcontact printing for forming conductive patterns. In some embodiments, the present method may also minimize transfer of the functional material to non-pattern areas on the substrate that typically occurs from stamp sagging (i.e., roof collapse in the recessed portions). The present method is applicable to forming patterns of functional material regardless of the relative dimensions of the raised surfaces and the recessed surfaces of the stamp.

The stamp may be formed in conventional fashion as understood by those skilled in the art of microcontact printing. For example, a stamp may be fabricated by molding and curing a layer of a material on a master having a surface presenting a relief form (that is in opposite of the stamp relief structure). The stamp may be cured by exposure to actinic radiation, heating, or combinations thereof. The stamp thus includes a layer of the elastomeric material, which may be referred to as an elastomeric layer, cured layer, or cured elastomeric layer. The stamp may also, for example, be fabricated by ablating or engraving a material in a manner that generates the relief structure. The relief structure of the stamp is such that the raised surface has a height from the recessed surface sufficient for selective contact of the raised surface with a substrate. The height from the recessed surface to the raised surface may also be called a relief depth. In one embodiment, the raised surface has a height from the recessed surface of about 0.2 to 20 micron. In another embodiment, the raised surface has a height from the recessed surface of about 0.2 to 2 micron. The elastomeric layer forming the stamp has a thickness that is not particularly limited provided that the relief structure can be formed in the layer for printing. In one embodiment, the thickness of the elastomeric layer is between 1 to 51 micron. In another embodiment, the thickness of the elastomeric layer is between 5 to 25 micron.

The elastomeric layer provides the resulting stamp with a modulus of elasticity of at least 10 MegaPascal, and preferably greater than 10 MegaPascal. The modulus of elasticity is a ratio of an increment of stress to an increment of strain. For the present method the modulus of elasticity is the Young's modulus where at low strains the relationship between stress and strain is linear, such that a material can recover from stress and strain. The modulus of elasticity may also be referred to as coefficient of elasticity, elasticity modulus, or elastic modulus. The modulus of elasticity is a mechanical property well known to those of ordinary skill in the art. A description of the modulus of elasticity and other mechanical properties of materials, and analysis thereof, can be found in Marks' Standard Handbook for Mechanical Engineers, eds. Avalone, E. and Baumeister III, T., 9^{th} edition, Chapter 5, McGraw Hill, 1987. A suitable method for determining the modulus of elasticity of the elastomeric stamp is described by Oliver and Pharr in J. Mater. Res. 7, 1564 (1992). This method is particularly suited for determining the modulus of elasticity for a thin elastomeric layer, such as the elastomeric layer forming the stamp that is less than 51 micron thick. The modulus of elasticity for the printing stamp can be measured on an indentation tester (Indenter) equipped with an indenter tip that is normal to a sample surface and having a known geometry. The indenter tip is driven into the sample by applying an increasing load up to some preset value. The load is then gradually decreased until partial or complete relaxation of the sample has occurred. Multiple sets of indentations in the sample can be done. The load/unload and displacement are recorded continuously throughout the test process to produce a load displacement curve from which mechanical properties, such as the modulus of elasticity and others, can be determined. The analysis of the load/unload curves for each indentation is conducted according to the method described by Oliver and Pharr originally introduced in the J. Mater. Res.

The material forming the stamp is elastomeric in order for at least a raised portion of the stamp to conform to a surface of the substrate so as to promote the complete transfer of the functional material thereto. The modulus of elasticity of at least 10 MegaPascal assures that the stamp can reproduce a fine resolution pattern of the functional material on the substrate by direct relief printing. Stamps with a modulus of elasticity of at least 10 MegaPascal, are capable of improved resolution by contact printing of the functional material to the substrate. In some embodiments of the stamp having a modulus of elasticity of at least 10 MegaPascal, the stamp exhibits less sagging in recessed areas. In one embodiment, the elastomeric stamp has a modulus of elasticity of at least 11 MegaPascal. In one embodiment, the elastomeric stamp has a modulus of elasticity of at least 15 MegaPascal. In another embodiment, the elastomeric stamp has a modulus of elasticity of at least 20 MegaPascal. In another embodiment, the elastomeric stamp has a modulus of elasticity of at least 40 MegaPascal.

The stamp can be fabricated from any material or combination of materials that is capable of reproducing by relief printing a pattern of functional material on the substrate. Polymeric materials suitable for forming the elastomeric stamp include, but are not limited to, for example, fluoropolymers; fluorinated compounds capable of polymerization; epoxy polymers, polymers of conjugated diolefin hydrocarbons, including polyisoprene, 1,2-polybutadiene, 1,4-polybutadiene, and butadiene/acrylonitrile; elastomeric block copolymers of an A-B-A type block copolymer, where A represents a non-elastomeric block, preferably a vinyl polymer and most preferably polystyrene, and B represents an elastomeric block, preferably polybutadiene or polyisoprene; and acrylate polymers. Examples of A-B-A block copolymers include but is not limited to poly(styrene-butadiene-styrene) and poly(styrene-isoprene-styrene). To the extent that silicone polymers, such as polydimethylsiloxane (PDMS), can provide the stamp with the modulus of elasticity of at least 10 MegaPascal, silicone polymers are also suitable materials. Selection of the material used for the elastomeric stamp may in part be dependent upon the composition of the functional material and its liquid and/or a composition of the surface modifying material and its liquid being applied to the stamp. For example, the material selected for the elastomeric stamp should be resistant to swelling while in contact with the surface modifying composition, and in particular, the liquid. Fluoropolymers are typically resistant to organic solvents (for the functional material). Certain solvents, such as chloroform, used with the functional material tend to swell silicone based stamps, such as PDMS. Swelling of the stamp will alter the capability to produce fine resolution patterns on the substrate. The polymeric material may be elastomeric or may become elastomeric upon curing. The polymeric material may itself be photosensitive and/or the polymeric material may be included with one or more additives in a composition to render the composition photosensitive.

In one embodiment, the material forming the elastomeric stamp is photosensitive such that the relief structure can be formed upon exposure to actinic radiation. The term “photosensitive” encompasses any system in which the photosensitive composition is capable of initiating a reaction or reactions, particularly photochemical reactions, upon response to actinic radiation. Upon exposure to actinic radiation, chain propagated polymerization of a monomer and/or oligomer is induced by either a condensation mechanism or by free radical addition polymerization. While all photopolymerizable mechanisms are contemplated, photosensitive compositions useful as elastomeric stamp material will be described in the context of free-radical initiated addition polymerization of monomers and/or oligomers having one or more terminal ethylenically unsaturated groups. In this context, the photoinitiator system when exposed to actinic radiation can act as a source of free radicals needed to initiate polymerization of the monomer and/or oligomer.

The composition is photosensitive since the composition contains a compound having at least one ethylenically unsaturated group capable of forming a polymer by photoinitiated addition polymerization. The photosensitive composition may also contain an initiating system activated by actinic radiation to induce photopolymerization. The polymerizable compound may have non-terminal ethylenically unsaturated groups, and/or the composition may contain one or more other components, such as a monomer, that promote crosslinking. As such, the term “photopolymerizable” is intended to encompass systems that are photopolymerizable, photocrosslinkable, or both. As used herein, photopolymerization may also be referred to as curing. The photosensitive composition forming the elastomeric stamp may include one or more constituents and/or additives, and can include, but is not limited to photoinitiators, one or more ethylenically unsaturated compounds (which may be referred to as monomers), fillers, surfactants, thermal polymerization inhibitors, processing aids, antioxidants, photosensitizers, and the like to stabilize or otherwise enhance the composition.

The photoinitiator can be any single compound or combination of compounds, which is sensitive to actinic radiation, generating free radicals which initiate the polymerization without excessive termination. Any of the known classes of photoinitiators, particularly free radical photoinitiators such as aromatic ketones, quinones, benzophenones, benzoin ethers, aryl ketones, peroxides, biimidazoles, benzyl dimethyl ketal, hydroxyl alkyl phenyl acetophone, dialkoxy actophenone, trimethylbenzoyl phosphine oxide derivatives, aminoketones, benzoyl cyclohexanol, methyl thio phenyl morpholino ketones, morpholino phenyl amino ketones, alpha halogennoacetophenones, oxysulfonyl ketones, sulfonyl ketones, oxysulfonyl ketones, sulfonyl ketones, benzoyl oxime esters, thioxanthrones, camphorquinones, ketocouumarins, and Michler's ketone may be used. In one embodiment, the photoinitiator can include a fluorinated photoinitiator that is based on known fluorine-free photoinitiators of the aromatic ketone type. Alternatively, the photoinitiator may be a mixture of compounds, one of which provides the free radicals when caused to do so by a sensitizer activated by radiation. Liquid photoinitiators are particularly suitable since they disperse well in the composition. Preferably, the initiator is sensitive to ultraviolet radiation. Photoinitiators are generally present in amounts from 0.001% to 10.0% based on the weight of the photosensitive composition.

Monomers that can be used in the composition activated by actinic radiation are well known in the art, and include, but are not limited to, addition-polymerization ethylenically unsaturated compounds. The addition polymerization compound may also be an oligomer, and can be a single or a mixture of oligomers. The composition can contain a single monomer or a combination of monomers. The monomer compound capable of addition polymerization can be present in an amount less than 5%, preferably less than 3%, by weight of the composition.

In one embodiment the elastomeric stamp is composed of a photosensitive composition that includes a fluorinated compound that polymerizes upon exposure to actinic radiation to form a fluorinated elastomeric-based material. Suitable elastomeric-based fluorinated compounds include, but are not limited to, perfluoropolyethers, fluoroolefins, fluorinated thermoplastic elastomers, fluorinated epoxy resins, fluorinated monomers and fluorinated oligomers that can be polymerized or crosslinked by a polymerization reaction. In one embodiment, the fluorinated compound has one or more terminal ethylenically unsaturated groups that react to polymerize and form the fluorinated elastomeric material. The elastomeric-based fluorinated compounds can be homopolymerized or copolymerized with polymers such as polyurethanes, polyacrylates, polyesters, polysiloxanes, polyamides, and others, to attain desired characteristics of the printing form precursor and/or the stamp suitable for its use. Exposure to the actinic radiation is sufficient to polymerize the fluorinated compound and render its use as a printing stamp, such that application of high pressure and/or elevated temperatures above room temperature is not necessary. An advantage of compositions containing fluorinated compounds that cure by exposure to actinic radiation is that the composition cures relatively quickly (e.g., in a minutes or less) and has a simple process development, particularly when compared to compositions that thermally cure such as PDMS based systems.

In one embodiment, the elastomeric stamp includes a layer of the photosensitive composition wherein the fluorinated compound is a perfluoropolyether (PFPE) compound. A perfluoropolyether compound is a compound that includes at least a primary proportion of perfluoroether segments, i.e., perfluoropolyether. The primary proportion of perfluoroether segments present in the PFPE compound is equal to or greater than 80 weight percent, based on the total weight of the PFPE compound. The perfluoropolyether compound may also include one or more extending segments that are hydrocarbons or hydrocarbon ethers that are not fluorinated; and/or, are hydrocarbons or hydrocarbon ethers that may be fluorinated but are not perfluorinated. In one embodiment, the perfluoropolyether compound includes at least the primary proportion of perfluoropolyether segments and terminal photoreactive segments, and optionally extending segments of hydrocarbon that are not fluorinated. The perfluoropolyether compound is functionalized with one or more terminal ethylenically unsaturated groups that render the compound reactive to the actinic radiation (i.e., photoreactive segments). The photoreactive segments may also be referred to as photopolymerizable segments.

The perfluoropolyether compound is not limited, and includes linear and branched structures, with linear backbone structures of the perfluoropolyether compound being preferred. The PFPE compound may be monomeric, but typically is oligomeric and a liquid at room temperature. The perfluoropolyether compound may be considered an oligomeric difunctional monomer having oligomeric perfluoroether segments. Perfluoropolyether compounds photochemically polymerize to yield the elastomeric layer of the stamp. An advantage of the PFPE based materials is that PFPEs are highly fluorinated and resist swelling by organic solvents, such as methylene chloride, chloroform, tetrahydrofuran, toluene, hexanes, and acetonitrile among others, which are desirable for use in microcontact printing techniques.

Optionally, the elastomeric stamp may include a support of a flexible film, and preferably a flexible polymeric film. The flexible support is capable of conforming or substantially conforming the elastomeric relief surface of the stamp to a printable electronic substrate, without warping or distortion. The support is also sufficiently flexible to be able to bend with the elastomeric layer of the stamp while peeling the stamp from the master. The support can be any polymeric material that forms a film that is non-reactive and remains stable throughout conditions for making and using the stamp. Examples of suitable film supports include cellulosic films such as triacetyl cellulose; and thermoplastic materials such as polyolefins, polycarbonates, polyimides, and polyester. Preferred are films of polyethylene, such as polyethylene terephthalate and polyethylene napthalate. Also encompassed within a support is a flexible glass. Typically the support has a thickness between 2 to 50 mils (0.0051 to 0.13 cm). Typically the support is in the form of a sheet film, but is not limited to this form. In one embodiment, the support is transparent or substantially transparent to the actinic radiation at which the photosensitive composition polymerizes.

After providing the elastomeric stamp, the method includes applying a first composition comprising a surface modifying material to at least the raised surface of the relief structure of the elastomeric stamp. In one embodiment, the surface modifying material is applied to the relief structure of the stamp, that is, to both the raised surfaces and recessed surface/s of the stamp. The surface modifying material on the at least the raised surface of the relief structure of the stamp aids the functional material in spreading or wetting on the same surface. The functional material can then uniformly cover or distribute on the surface the stamp that will ultimately contact the substrate and print the pattern of functional material. The surface or surfaces of the relief structure of the stamp having the surface modifying material allows for some functional materials, which are incompatible with the material used to form the elastomeric stamp, to form a uniform layer on the structure or structures. The surface or surfaces of the relief structure of the stamp having the surface modifying material may also aid in the imagewise transfer or printing of the pattern of the functional material on the substrate.

The surface modifying material should be capable of being deposited on at least the raised surface of the stamp by any suitable method. The surface modifying material should also be capable of forming a film that does not crack, peel, or flake off from the stamp during manipulation or operation of the stamp. The surface modifying material may have a glass transition temperature that is near or below room temperature to minimize cracking when the stamp is operated under ambient conditions. Ideally, the surface modifying material may have a glass transition temperature that closely approximates that of the material comprising the stamp. In one embodiment, the surface modifying material forms a continuous, smooth and mechanically robust film or a substantially continuous, smooth and mechanically robust film on the stamp. Once on the stamp, the surface modifying material should not be perturbed or re-dissolved by the application of the functional material. Once on the stamp, the surface modifying material will enhance (or modify) the wetting behavior of the functional material. The surface modifying material will provide a surface tension that is different from the surface tension of the stamp itself for the functional material. Once on the stamp, the surface modifying material should not be altered at the conditions used for transferring the functional material to the substrate. Particularly if elevated temperatures are used during transfer of the functional material, the surface modifying material should not melt or soften. Optionally, if the surface modifying material transfers with the functional material to the substrate, the surface modifying material may be capable of removal from the functional material after transfer by any suitable means including dissolution.

Materials suitable as the surface modifying material are not limited provided that the surface modifying material meets the above capabilities. Examples of suitable surface modifying material include, but are not limited to, amphiphilic compounds, for example, alkyltrichlorosilane, hexamethyldisilazane (HMDS), and pentafluorophenylpropyltrimethoxysilane; organo-functional silane compounds, for example, tris(3-trimethoxysilylpropyl)isocyanurate, N,N′-bis[(3-trimethoxysilyl)propyl]ethylenediamine; polyelectrolyte compounds, for example, poly(allylamine hydrochloride); biologically-active materials, for example, phospholipids; acrylic polymers and their copolymers; methacrylic polymers and their copolymers; vinyl polymers and their copolymers; di-, tri-, and multi-block copolymers of vinyl polymers and (meth)acrylic polymers, for example, polystyrene-polymethylmethacrylate block copolymer; conjugated aromatic polymers and conjugated aromatic copolymers, for example, poly(para-phenylene vinylene) polymers and copolymers.

The surface modifying material can be incorporated in solution in order to aid in the handling or application of the material to the stamp. The surface modifying material can be dispersed or dissolved or suspended in a liquid, forming a composition for application to the stamp. The liquid used for the surface modifying material is not limited and can include organic compounds and aqueous compounds. In one embodiment, the liquid is an organic compound that is an alcohol-based compound. The liquid may be a solvent, that is a substance which is capable of dissolving another substance (i.e., surface modifying material) to form a uniform mixture, or may be a carrier compound capable of dispersing or suspending the material in solution sufficient to conduct the steps of the present method. The liquid, whether solvent or carrier, and the surface modifying material should at least be capable of wetting at least the raised surface of the stamp during application. The surface modifying material may be present in the liquid from 0.1 to 30% by weight based on the total weight of the composition. In one embodiment the surface modifying material may be present in the liquid from 0.001 to 15% by weight based on the total weight of the composition. The liquid may include one or more than one compounds as a solvent or carrier for the surface modifying material. In one embodiment, the liquid includes one solvent for the surface modifying material. In one other embodiment, the liquid solution includes one carrier compound for the surface modifying material. In another embodiment, the liquid includes two solvents, that is, a co-solvent mixture, for the surface modifying material. In the embodiment where a co-solvent mixture is used, the components in the mixture may be selected according to one or more of the following guidelines: (1) The evaporation rate (i.e., volatility) of the individual solvent components are different. (2) The solvating power of the individual solvent components for a particular surface modifying material are different. The solvating power and the volatility of the individual solvent components are different enough such that a gradient in the composition and/or during removal of the liquid is created. (3) The individual solvent components are miscible with each other over the composition range that occurs during removal of the liquid from the relief structure of the stamp. (4) The co-solvent mixture continues to wet the raised surface of the stamp during removal of the liquid from the stamp. One example of a co-solvent mixture includes a very good solvent (of the surface modifying material) that is highly volatile that forms a binary solvent solution with a poorer solvent that is less volatile. As the binary solvent solution evaporates from the raised surface of the stamp, the solution composition continuously changes (gradient). The solution gradient can drive changes in the characteristics of the surface modifying material during removal of the liquid to form the film on the stamp.

The surface modifying material or the composition of the surface modifying material and the liquid can be applied to the stamp by any suitable method, including but not limited to, injection, pouring, liquid casting, jetting, immersion, spraying, vapor deposition, and coating. Examples of suitable methods of coating include spin coating, dip coating, slot coating, roller coating, and doctor blading. In one embodiment, the surface modifying material composition is applied to the stamp and forms a layer on the relief structure of the stamp, that is, the composition forms a layer on the raised surface/s and the recessed surface/s. The layer of surface modifying material composition on the stamp can be continuous or discontinuous. The thickness of the layer of the surface modifying material is not particularly limited. In one embodiment, the thickness of the surface modifying material layer is typically less than the relief height (difference between the raised surface and the recessed surface) of the stamp.

The surface modifying material or composition of the surface modifying material should be capable of forming a layer on at least the raised surface of the relief structure of stamp. Beyond the requirement for the elastomeric modulus of the stamp, certain other properties of the elastomeric stamp, such as, the solvent resistance of the stamp material, as well as certain properties of the composition of the surface modifying material, such as, the boiling point of a solvent and solubility of the surface modifying material in the solvent, may influence the capability of a particular surface modifying material to form a layer and aid in the wetting of the functional material, but it is well within the skill of those in the art of microcontact printing to determine an appropriate combination of surface modifying material and elastomeric stamp.

If the composition of the surface modifying material and the liquid is applied to the stamp, some or all of the liquid from the composition is removed and the surface modifying material remains on the stamp. The liquid from the composition on the relief structure is removed sufficiently to form a film of the surface modifying material on at least the raised surface of the stamp. If more than one compound is used as the liquid for the surface modifying material composition, some or all of the more than one compound are removed to form the film. Removing by may be accomplished in any manner, including, using gas jets, blotting with an absorbent material, evaporation at room temperature or an elevated temperature, etc. In one embodiment, removing can occur by drying during the application of the surface modifying material on the stamp. Effective drying can be aided by selecting a solvent for the surface modifying material that has a relatively low boiling point and/or by application of very thin layer (i.e., less than about 1 micron) of the composition of the surface modifying material. The liquid is sufficiently removed from the composition layer provided that the functional material can sufficiently wet and form a film on the layer of the surface modifying material. In one embodiment, the film of the surface modifying material on the stamp has a thickness between 0.001 and 2 micron (micrometers). In another embodiment, the film layer of surface modifying material on the stamp has a thickness between 0.01 to 1 micron.

In one embodiment, the functional material is a material that is patterned by microfabrication to facilitate an operation in a variety of components and devices. The functional material can be an active material or an inactive material. Active materials include, but are not limited to, electrically active materials, photoactive materials, and biologically active materials. As used herein, the terms “electrically active”, “photoactive” and “biologically active” refer to a material which exhibits a predetermined activity in response to a stimulus, such as an electromagnetic field, an electrical potential, solar or other energy radiation, a biostimulation field, or any combination thereof. Inactive materials include, but are not limited to, insulating materials, such as dielectric materials; planarization materials; barrier materials; and confinement materials. In one embodiment, the planarization material is printed on top of a pattern of pixels in color filters to render all pixels the same height. In one embodiment, the barrier material is printed pattern to form a barrier so that charges in the cathode facilitate charge injection into a light emitting polymer layer in an organic light emitting diode (OLED). In one embodiment, the confinement material is printed as a pattern that restricts the expansion of a subsequently applied liquid to a particular area defined by the pattern of confinement material. The functional materials for the inactive materials are not limited to only those used in the embodiments described above. The active materials and inactive materials can be organic or inorganic. Organic materials can be polymeric materials, or small molecule materials.

The functional material is not limited, and includes, for example, conductive materials, semi-conductive materials, and dielectric materials. Examples of conductive materials for use as a functional material include, but are not limited to, indium-tin oxide; metals, such as silver, gold, copper, and palladium; metal complexes; metal alloys; etc. Examples of semiconductive materials include, but are not limited to, silicon, germanium, gallium arsenide, zinc oxide, and zinc selenide.

The functional material can be of any form including particulate, polymeric, molecular, etc. Typically, semiconducting materials and dielectric materials are polymeric, but are not limited to this form, and functional materials can include soluble semiconducting molecules.

Functional materials for use in the present method also include nanoparticles of conductive, semi-conductive, and dielectric materials. Nanoparticles are microscopic particles whose size is measured in nanometers (nm). Nanoparticles include particles having at least one dimension less than 200 nm. In one embodiment, the nanoparticles have a diameter of about 3 to 100 nm. At the small end of the size range, the nanoparticles may be referred to as clusters. The shape of the nanoparticles is not limited and includes nanospheres, nanorods, and nanocups. Nanoparticles made of semiconducting material may also be called quantum dots, if the particles are small enough (typically less than 10 nm) that quantization of electronic energy levels occurs. Semiconducting materials include light-emitting quantum dots. A bulk material generally has constant physical properties regardless of its size, but for nanoparticles this is often not the case. Size dependent properties are observed such, as quantum confinement in semiconductor particles, surface plasmon resonance in some metal particles and superparamagnetism in magnetic materials. The functional material includes but is not limited to semi-solid nanoparticles, such as liposome; soft nanoparticles; nanocrystals; hybrid structures, such as core-shell nanoparticles. The functional material includes nanoparticles of carbon, such as carbon nanotubes, conducting carbon nanotubes, and semiconducting carbon nanotubes. Metal nanoparticles and dispersions of gold, silver and copper are commercially available from Nanotechnologies, and ANP.

The term “photoactive” is intended to mean any material that exhibits photoluminescence, electroluminescence, coloration, or photosensitivity. The term is intended to include, among others, dyes, optical whiteners, photoluminescent materials, compounds reactive to actinic radiation, and photoinitiators. In one embodiment, photoactive materials encompasses any material or combination of materials which is capable of initiating a reaction or reactions, particularly photochemical reactions, upon response to actinic radiation. Photoactive materials can include a compound which itself may be reactive to actinic radiation, and/or may include a composition of one or more compounds, such as monomers and photoinitiators, that render the composition reactive to actinic radiation. Suitable photoactive materials for the functional material include those described above as photosensitive compositions and materials suitable for the elastomeric stamp. In one embodiment the photoactive materials can be one or more fluorinated compounds, such as fluoropolymers, fluorinated monomers, and fluorinated oligomers, as described above for the elastomeric stamp. In another embodiment the functional material is an organic light emitting polymer

Further examples of functional materials that may be referred to as small molecule materials, can include, but are not restricted to, organic dyes, semi-conducting molecules, fluorescent chromophores, phosphorescent chromophores, pharmacologically active compounds, biologically active compounds and compounds having catalytic activites, that alone or in various combinations with other materials, are suitable for the fabrication of patterned devices useful for electronic, sensory or diagnostic applications.

Biologically active materials, which may also be called bio-based materials, for use in the present invention can include, but are not limited to, deoxyribonucleic acids (DNAs) of various molecular weights that can be employed as templates or scaffolds to position other materials that bind to DNA into well-defined geometries, and proteins, poly(oligo) peptides, and poly(oligo) saccharides, that alone or in various combinations with other materials, are suitable for the fabrication of patterned devices for electronic, sensory or diagnostic applications.

In an alternate embodiment, the present method can use the elastomeric stamp having the surface modifying material on the relief structure to form a pattern of a mask material on a substrate, as described in pending U.S. patent application Ser. No. 11/50806, filed Aug. 23, 2006 (attorney docket number IM-1336). In this embodiment, the mask material can be treated as a functional material of the present invention, that is, the mask material can be applied on at least the raised surface of the stamp and transferred to the substrate to form a pattern. The mask material should at least have the same capabilities as described herein for the functional material, with the exception that the mask material does not facilitate an operation as an active material or an inactive material in a variety of components and devices. In this embodiment, the recessed surfaces of the relief structure of the elastomeric stamp represent the pattern of the functional material that will ultimately be formed on the substrate, and the raised surfaces forming the pattern of the mask material on the substrate represent the background or featureless areas on the substrate. The pattern of the mask material on the substrate is the opposite or the negative of a pattern of a functional material desired for the electronic component or device. The pattern of the mask material on the substrate correspondingly forms a pattern of open area on the substrate. Functional material that does facilitate an operation as an active material or an inactive material in a variety of components and devices as described above is applied to at least pattern of open area on the substrate. Subsequent to the application of the functional material, the mask material is removed. Materials suitable as the mask material are not limited provided that the mask material is capable of (1) forming a layer on at least the raised surface of the relief structure of stamp; (2) transferring a pattern according to the relief structure to the substrate; and (3) removing from the substrate without detrimentally impacting the functional material.

The functional material is typically dispersed or dissolved or suspended in a liquid, forming a composition for application to the stamp. The liquid used for the functional material is not limited and can include organic compounds and aqueous compounds. In one embodiment, the liquid is an organic compound that is an alcohol-based compound. The liquid may be a solvent, that is a substance which is capable of dissolving another substance (i.e., functional material) to form a uniform mixture, or may be a carrier compound capable of dispersing or suspending the material in solution sufficient to conduct the steps of the present method. The liquid, whether solvent or carrier, and the functional material should at least be capable of wetting at least the raised surface of the stamp during application. The functional material may be present in the liquid from 0.1 to 30% by weight based on the total weight of the composition. The liquid may include one or more than one compounds as a solvent or carrier for the functional material. In one embodiment, the liquid includes one solvent for the functional material. In one other embodiment, the liquid solution includes one carrier compound for the functional material. In another embodiment, the liquid includes two solvents, that is, a co-solvent mixture, for the functional material. In the embodiment where a co-solvent mixture is used, the components in the mixture may be selected according to one or more of the following guidelines: (1) The evaporation rate (i.e., volatility) of the individual solvent components are different. (2) The solvating power of the individual solvent components for a particular functional material are different. The solvating power and the volatility of the individual solvent components are different enough such that a gradient in the composition and/or during removal of the liquid is created. (3) The individual solvent components are miscible with each other over the composition range that occurs during removal of the liquid from the relief structure of the stamp. (4) The co-solvent mixture continues to wet the raised surface of the stamp during removal of the liquid from the stamp. One example of a co-solvent mixture includes a very good solvent (of the functional material) that is highly volatile that forms a binary solvent solution with a poorer solvent that is less volatile. As the binary solvent solution evaporates from the raised surface of the stamp, the solution composition continuously changes (gradient). The solution gradient can drive changes in the characteristics of the functional material during removal of the liquid to form the film on the stamp. Characteristics that may change as a result of such a drying gradient include aggregation for small aromatic molecules, such as semiconductive materials, and conformation for (bio)polymers such as DNA or semi-conducting polymers. The film of the functional material that results from the drying gradient may have different characteristics, which may be physical, or chemical, or biological, that may possibly influence the state of the functional material pre- or post-transfer to the substrate.

The composition of the functional material and the liquid is provided on the stamp by applying the composition onto the layer of the surface modifying material on at least the raised surface of the relief structure of the stamp. The composition of the functional material and the liquid can be applied to the surfaces of the stamp having the layer of the surface modifying material by any suitable method, including but not limited to, injection, pouring, liquid casting, jetting, immersion, spraying, vapor deposition, and coating. Examples of suitable methods of coating include spin coating, dip coating, slot coating, roller coating, and doctor blading. In one embodiment, the composition is applied to the stamp and forms a layer on the relief structure of the stamp, that is, the composition forms a layer on the raised surface/s and the recessed surface/s. The layer of composition on the stamp can be continuous or discontinuous. The thickness of the layer of the composition is not particularly limited. In one embodiment, the thickness of the composition layer is typically less than the relief height (difference between the raised surface and the recessed surface) of the stamp.

The composition should be capable of forming a layer on at least the raised surface of the relief structure of stamp having the layer of the surface modifying material. Beyond the requirement for the elastomeric modulus of the stamp, certain other properties of the elastomeric stamp, such as, the solvent resistance of the stamp material, as well as certain properties of the composition of the functional material, such as, the boiling point of a solvent and solubility of the functional material in the solvent, may influence the capability of a particular functional material to form a layer on the layer of the surface modifying material and transfer as a pattern to the substrate, but it is well within the skill of those in the art of microcontact printing to determine an appropriate combination of functional material and elastomeric stamp.

In one embodiment, the functional material is in a liquid solution of a solvent for application to the substrate. In another embodiment, the functional material is in a co-solvent mixture for application to the substrate. The functional material, particularly when in the form of nanoparticles, is suspended in a carrier system, for application.

After the composition of the functional material and the liquid has been applied to at least the raised surface of the stamp having the layer of the surface modifying material, some or all of the liquid from the composition is removed and the functional material remains on the stamp. The liquid from the composition on the relief structure is removed sufficiently to form a film of the functional material on at least the raised surface of the stamp. If more than one compound is used as the liquid for the functional material composition, some or all of the more than one compound are removed to form the film. Removing by may be accomplished in any manner, including, using gas jets, blotting with an absorbent material, evaporation at room temperature or an elevated temperature, etc. In one embodiment, removing can occur by drying during the application of the functional material on the stamp. Effective drying can be aided by selecting a solvent for the functional material that has a relatively low boiling point and/or by application of very thin layer (i.e., less than about 1 micron) of the composition of the functional material. The liquid is sufficiently removed from the composition layer provided that a pattern of the functional material according to the relief structure transfers to the substrate. In one embodiment, the film of the functional material on the stamp has a thickness between 0.001 and 2 micron. In another embodiment, the film layer of functional material on the stamp has a thickness between 0.01 to 1 micron.

In one embodiment the functional material is substantially free of liquid, that is the solvent or carrier, to form a film on the relief structure. In another embodiment, the liquid is substantially removed from the composition form a dried film of the functional material on at least the raised surface, and the dried film is exposed to a compound in its vaporized state in order to enhance transfer to the substrate. The vaporized compound is not limited, and can include water vapor or an organic compound vapor. Although not limited to the following, it is contemplated that the exposure of the dried film to the vaporized compound plasticizes the dried film to the extent that the film becomes slightly more malleable and increases the capability of the functional material to adhere to the substrate. Typically the effect of the vaporized compound on the dried film is temporary and transfer of the film to the substrate should immediately follow or substantially immediately follow.

Transferring the functional material from the raised surface of the relief structure to the substrate creates a pattern of the functional material on the substrate. Transferring may also be referred to as printing. Contacting the functional material on the raised surface to the substrate transfers the functional material, such that the pattern of functional material forms when the stamp is separated from the substrate. In one embodiment, all or substantially all the functional material positioned on the raised surface(s) transfer to the substrate. The separation of the stamp from the substrate may be accomplished by any suitable means, including but not limited to peeling, gas jets, liquid jets, mechanical devices etc.

Optionally, pressure may be applied to the stamp to assure contact and complete transfer of the functional material to the substrate. Suitable pressure used to transfer the functional material to the substrate is less than 5 lbs./cm², preferably less than 1 lbs./cm², more preferably 0.1 to 0.9 lbs./cm², and most preferably about 0.5 lbs./cm². Transfer of the functional material to the substrate may be accomplished in any manner. Transferring the functional material may be by moving the relief surface of the stamp to the substrate, or by moving the substrate to the relief surface of the stamp, or by moving both the substrate and the relief surface into contact. In one embodiment, the functional material is transferred manually. In another embodiment, the transfer of the functional material is automated, such as, for example, by a conveyor belt; reel-to-reel process; directly-driven moving fixtures or pallets; chain, belt or gear-driven fixtures or pallets; a frictional roller; printing press; or a rotary apparatus. The thickness of the layer of functional material is not particularly limited, with typical thickness of the layer of functional material on the substrate between 10 to 10000 angstrom (0.001 to 1 micron).

The present method typically occurs at room temperature, that is, at temperatures between 17 to 30° C. (63 to 86° F.), but is not so limited. The present method can occur at an elevated temperature, up to about 100° C., provided that the heat does not detrimentally impact the elastomeric stamp, the functional material, and the substrate and their ability to form the pattern on the substrate. In an embodiment where the substrate includes an adhesive layer, it may be useful to carry out the present method at a temperature higher than room temperature to aid in the transfer of the functional material from the stamp to the substrate.

In one embodiment, the layer of the surface modifying material remains with the elastomeric stamp after transfer of the functional material to the substrate. In another embodiment, the surface modifying material on the raised surface transfers with the functional material to the substrate. In this embodiment, the surface modifying material can be removed from the pattern of functional material formed on the substrate by any suitable means provided that the pattern of functional material is not disturbed or altered. In one embodiment, the surface modifying material is removed by washing with a solvent of the surface modifying material (and which is not a solvent to the functional material).

The substrate is not limited, and can include, plastic, polymeric films, metal, silicon, glass, fabric, paper, and combinations thereof, provided that the pattern of functional material can be formed thereon. The substrate can be opaque or transparent. The substrate can be rigid or flexible. The substrate may include one or more layers and/or one or more patterns of other materials, before the pattern of the functional material according to the present method is formed on the substrate. A surface of the substrate can include an adhesion-promoting surface, such as a primer layer, or can be treated to promote adhesion of an adhesive layer or the functional material to the substrate. Optionally, the substrate can include an adhesive layer to aid in the transfer of the functional material from the stamp to the substrate. In one embodiment, the adhesive has a glass transition temperature above room temperature. By heating the substrate having an adhesive layer above room temperature, the adhesive layer can soften or become tacky and aid in the adhesion of the functional material to the substrate. The substrate need not have any treatment or adhesive layers, provided that there is a sufficient difference in the surface energy of the stamp and the substrate to drive the transfer of functional material to the substrate. Suitable substrates include, for example, a metallic film on a polymeric, glass, or ceramic substrate, a metallic film on a conductive film or films on a polymeric substrate, metallic film on a semiconducting film on a polymeric substrate. Further examples of suitable substrates include, for example, glass, indium-tin-oxide coated glass, indium-tin-oxide coated polymeric films; polyethylene terephthalate, polyethylene naphthalate, polyimides, silicon, and metal foils. The substrate can include one or more charge injection layers, charge transporting layers, and semiconducting layers on to which the pattern is transferred.

Materials suitable as the adhesive for the substrate are not limited provided that the adhesive can form a layer by any means and can aid in the transfer of the functional material to the substrate. In one embodiment, the adhesive is acrylic latex. In another embodiment, the adhesive is a thermally-activated adhesive that is a solid material which softens at elevated temperatures to act as an adhesive. Examples of thermally-activated adhesives include, but are not limited to, polyamides, polyacrylates, polyolefins, polyurethanes, polyisobutylenes, polystyrenes, polyvinyl resins, polyester resins, and copolymers and blends of these and other polymers. Further examples of adhesives can be found in “Handbook of Adhesives”, edited by I. Skeist, second edition, Van Nostrand Reinhold Company, New York, 1977. The adhesive layer has a thickness between about 10 to about 10000 angstrom.

Optionally, the pattern of functional material on the substrate may undergo further treatment steps such as, heating, exposing to actinic radiation sources such as ultraviolet radiation and infrared radiation, etc. In an embodiment where the functional material is in the form of nanoparticles, the additional treatment step may be necessary to render the functional material operative. For instance, when the functional material is composed of metal nanoparticles, the pattern of functional material may be heated to sinter the particles and render the lines of the pattern conductive. Sintering is forming a coherent bonded mass by heating a metal powder, such as in the form of nanoparticles, without melting. Heating the conductive material to a temperature less than about 220° C., and preferably less than about 140° C., sinters the nanoparticle conductive material into a continuous functional film.

The present method provides a method to form a pattern of a functional material on a substrate for use in devices and components in a variety of applications, including but no limited to, electronic, optical, sensory, and diagnostic applications. The method can be used to form patterns of active materials or inactive materials for use in electronic devices and components and in optical devices and components. Such electronic and optical devices and components include, but are not limited to radio frequency tags (RFID), sensors, and memory and backpanel displays. The method can be used to form patterns of conductive materials, semiconductive materials, dielectric materials on the substrate. The method can be used to form patterns of biological materials and pharmacologically active materials on the substrate for use in sensory or diagnostic applications. The method can form the functional material into a pattern that forms barrier walls for cells or pixels to contain other materials, such as light emitting materials, color filter pigmented materials, or a pattern that defines the channel length between source and drain electrode delivered from solution. The pattern of barrier walls may also be referred to as a confinement layer or barrier layer. The method can form the functional material into a pattern that forms barrier walls that creates cells for use as color filter pixels. The color filter pixels can be filled with colorant materials for color filters, including pigmented colorants, dye colorants. The method can form the functional material into transistor channels for top gate devices in which other materials, such as source materials and drain materials, are delivered to the channels. The method can form the functional material into transistor channels on a semiconducting layer of the substrate for bottom gate devices in which source materials and drain materials are delivered to the channels. The other materials can be delivered into the cells on the substrate as a solution by any means, including ink jet.

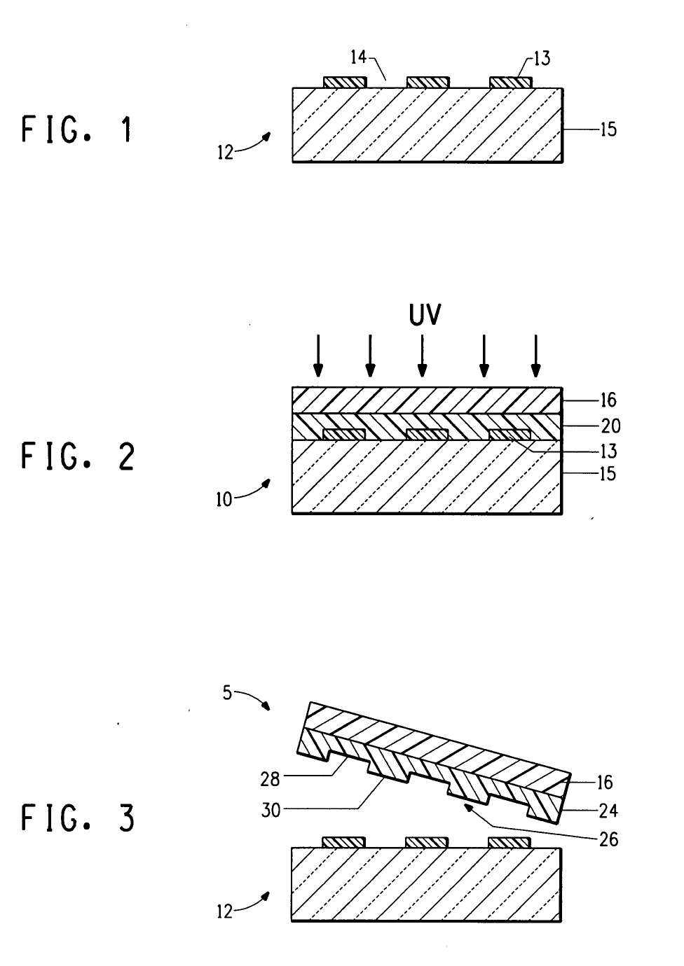

FIGS. 1 through 3 show one embodiment of a method of preparing a stamp 5 from a stamp precursor 10 in a molding operation. FIG. 1 depicts a master 12 having a pattern 13 of a negative relief of the microelectronic features formed on a surface 14 of a master substrate 15. The master substrate 15 can be any smooth or substantially smooth metal, plastic, ceramic or glass. In one embodiment the master substrate is a glass or silicon plane. Typically the relief pattern 13 on the master substrate 15 is formed of a photoresist material, according to conventional methods that are well within the skill in the art. Plastic grating films and quartz grating films can also be used as masters. If very fine features on the order of nanometers are desired, masters can be formed on silicon wafers with e-beam radiation.

The master 12 may be placed in a mold housing and/or with spacers (not shown) along its perimeter to assist in the formation of a uniform layer of the photosensitive composition. The process to form the stamp can be simplified by not using the mold housing or spacers.

In FIG. 2, a photosensitive composition is introduced to form a layer 20 onto the surface of the master 12 having the relief pattern 13. The photosensitive composition can be introduced on to the master 12 by any suitable method, including but not limited to, injection, pouring, liquid casting and coating. In one embodiment, the photosensitive composition is formed into the layer 20 by pouring the liquid onto the master. The layer of the photosensitive composition 20 is formed on the master 12 such that after exposure to actinic radiation, the cured composition forms a solid elastomeric layer having a thickness of about 5 to 50 micron. In the embodiment shown, an optional support 16 is positioned on a side of the photosensitive composition layer 20 opposite the master 12 such that an adhesive layer if present, is adjacent the layer of the photosensitive composition, to form the stamp precursor 10. The support 16 can be applied to the composition layer in any manner suitable to attain the stamp precursor 10. Upon exposure to actinic radiation, which is ultraviolet radiation in the embodiment shown, through the transparent support 16 of the stamp precursor 10, the photosensitive layer 20 polymerizes and forms an elastomeric layer 24 of the composition for the stamp 5. The layer of the photosensitive composition 20 cures or polymerizes by exposure to actinic radiation. Further, typically the exposure is conducted in a nitrogen atmosphere, to eliminate or minimize the presence of atmospheric oxygen during exposure and the effect that oxygen may have on the polymerization reaction.

The printing form precursor can be exposed to actinic radiation, such as an ultraviolet (UV) or visible light, to cure the layer 20. The actinic radiation exposes the photosensitive material through the transparent support 16. The exposed material polymerizes and/or crosslinks and becomes a stamp or plate having a solid elastomeric layer with a relief surface corresponding to the relief pattern on the master. In one embodiment, suitable exposure energy is between about 10 and 20 Joules on a 365 nm I-liner exposure unit.

Actinic radiation sources encompass the ultraviolet, visible, and infrared wavelength regions. The suitability of a particular actinic radiation source is governed by the photosensitivity of the photosensitive composition, and the optional initiator and/or the at least one monomer used in preparing the stamp precursor. The preferred photosensitivity of stamp precursor is in the UV and deep visible area of the spectrum, as they afford better room-light stability. Examples of suitable visible and UV sources include carbon arcs, mercury-vapor arcs, fluorescent lamps, electron flash units, electron beam units, lasers, and photographic flood lamps. The most suitable sources of UV radiation are the mercury vapor lamps, particularly the sun lamps. These radiation sources generally emit long-wave UV radiation between 310 and 400 nm. Stamp precursors sensitive to these particular UV sources use elastomeric-based compounds (and initiators) that absorb between 310 to 400 nm.

In FIG. 3, the stamp 5, which includes the support 16, is separated from the master 12 by peeling. The support 16 on the stamp 5 is sufficiently flexible in that the support and the stamp can withstand the bending necessary to separate from the master 12. The support 16 remains with the cured elastomeric layer 24 providing the stamp 5 with the dimensional stability necessary to reproduce micropatterns and microstructures associated with soft lithographic printing methods. The stamp 5 includes on a side opposite the support 16 a relief structure 26 having recessed surfaces 28 and raised surfaces 30 corresponding to the negative of the relief pattern 13 of the master 12. The relief structure 26 has a difference in height between the raised portion 30 and the recessed portion 28, that is a relief depth. The relief structure 26 of the stamp 5 forms a pattern of raised surfaces 30 for printing the functional material 32 on a substrate 34 and recessed surface portions 28 which do not print.

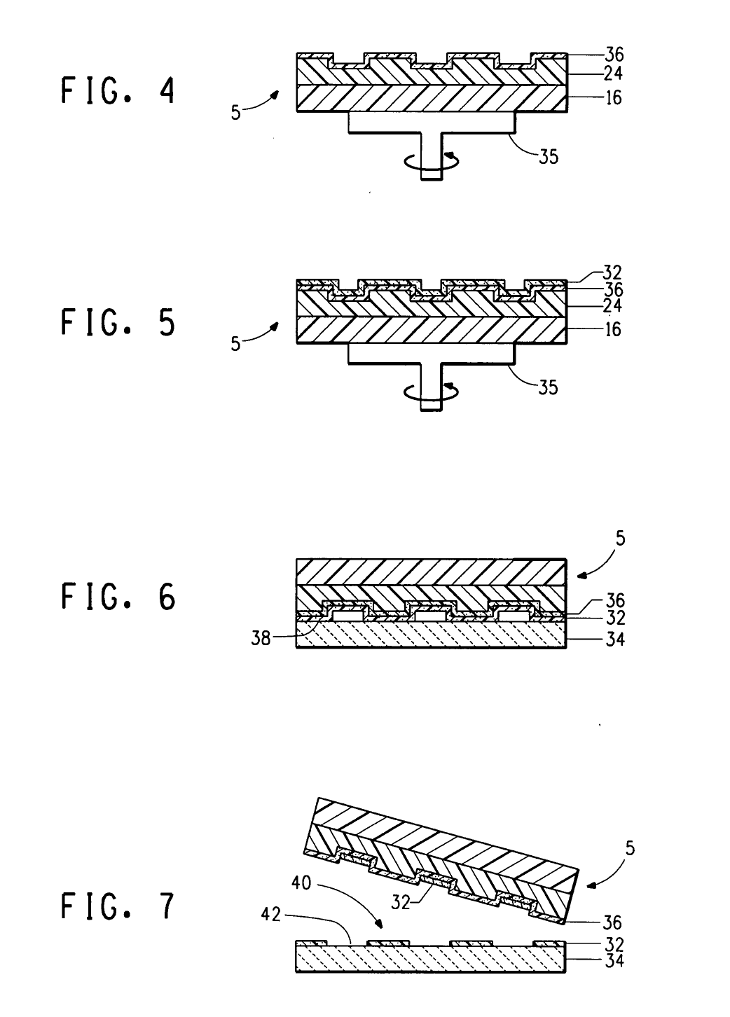

In FIG. 4, the stamp 5 resides on a platform 35 of a spin coating device as one embodiment for applying the surface modifying material 36 onto the relief structure 26 of the stamp 5. The surface modifying material 36 is applied to the relief structure 26 of the stamp 5 and the platform is rotated to form a relatively uniform, continuous layer of the surface modifying material. After application to the stamp 5 the surface modifying material 36 may be dried to remove liquid by evaporation at room temperature.

In FIG. 5, the stamp 5 resides on the platform 35 of the spin coating device as one embodiment for applying the functional material 32 onto the layer of the surface modifying material 36 residing on the relief structure 26 of the stamp 5. The functional material 32 is applied to the is layer of the surface modifying material 36 on the stamp 5 and the platform is rotated to form a relatively uniform, continuous layer of the functional material. After application to the stamp 5 the functional material is dried to remove the liquid by evaporation at room temperature.

In FIG. 6, the substrate 34 and the stamp 5 (having the layer of functional material 32 and the layer of the surface modifying material 36) are positioned adjacent one another so that the functional material on the raised surfaces 30 of the stamp 5 contact a surface 38 of the substrate 34.

In FIG. 7, the stamp 5 is separated from the substrate 34, and the functional material 32 contacting the substrate remains on the substrate, transferring to form a pattern 40 of the functional material. In this embodiment, the surface modifying material 36 remained with the stamp 5. The substrate 34 includes the pattern 40 of functional material 32 and open areas 42 where no functional material resides. The functional material 32 that resides on the substrate 34 creates a pattern 40 for the electronic device or component.

The present method uses an elastomeric stamp having a modulus of elasticity of at least 10 MegaPascal (Mpa) and having the surface modifying material residing on the relief structure, which provides the capability to form features of various functional materials on the substrate of less than 50 micron resolution to at least as fine as 1 to 5 micron. The present method is particularly suited for embodiments in which the functional material or the composition of the functional material is incompatible or substantially incompatible with the material forming the elastomeric stamp. An example of an incompatible embodiment is one in which the composition of the functional material may cause the elastomeric stamp to swell in the liquid of the composition, if the functional material composition were applied directly to the relief structure of the stamp. Another example of an incompatible embodiment is one in which the functional material or composition of the functional material when applied directly to the relief structure of the stamp, does not sufficiently wet or spread on at least the raised surface to provide a uniform layer for printing to the substrate. Another example of an incompatible embodiment is one in which the functional material and the material forming the elastomeric stamp chemically react. Another example of an incompatible embodiment is one in which the functional material is denatured by contact with the material forming the stamp. The functional material in this case may be a structurally sensitive bio-macromolecule like DNA or an enzyme. Yet another example of an incompatible embodiment is one in which the functional material is contaminated by mobile (uncured) species that migrate to the relief surface of the stamp. Due to the nature of photosensitive systems, the elastomeric stamp formed from a photosensitive composition may have the mobile species present even after the composition is cured or substantially cured (crosslinked) to form the relief structure. The capability of the present method to form a pattern of functional material of suitable line resolution may be influenced by, but by no means limited to, the choice of material for the elastomeric stamp, the surface modifying material being used, the functional material being printed, the composition of the functional material, the conditions at which the present method is conducted, etc. It will be appreciated that determining optimal materials and conditions to provide the desired line resolution for end-use applications in electronic devices and components would be routine to those of ordinary skill in the art.

### EXAMPLES

Unless otherwise indicated, all percentages are by weight of the total composition.

### Example 1

The following example demonstrates the printing of a high resolution, high conductivity silver pattern onto a flexible substrate using an elastomeric polyfluoropolyether (PFPE) stamp whose surface characteristics have been modified by the application of a thin polymeric layer.

### Master Preparation:

A 0.6 micrometer thick layer of a negative photoresist, SU-8 type 2 (from MicroChem, Newton, Mass.) was coated onto a silicon wafer at 3000 rpm for 60 sec. The wafer with the coated photoresist film was heated 65° C. for 1 minute and then baked at 95° C. for 1 minute to fully dry the film. The baked film was then exposed for 5 sec in I-liner (OAI Mask Aligner, Model 200) at 365 nm through a mask having a pattern of lines and spaces and rectangles with dimensions varying from 5 to 250 micron, and post-baked at 65° C. for 1 min. After a final bake at 95° C. for 1 minute the non-exposed photoresist was developed in SU-8 developer for 1 minute. The developed film was dried with nitrogen and formed a pattern on the wafer, which was used as a master for the stamp.

### Support Preparation:

A support for the stamp was prepared with a layer of an adhesive prior to the molding of the PFPE stamp. A 5 micron layer of NOA73, a UV curable, optically-clear adhesive (Norland Products; Cranbury, N.J.) was spin coated onto a 5 mil (0.0127 cm) Melinex® 561 polyester film support at 3000 rpm. Afterwards, the film was cured by exposure to ultraviolet radiation (350400 nm) at 1.6 watts power (20 mWatt/cm²) for 90 seconds in a nitrogen environment.

### PFPE Stamp Preparation

A perfluoropolyether compound E10-DA was used as received and supplied by Sartomer as product type CN4000. The E10-DA has a structure according to the following Formula, wherein R and R′ are each an acrylate, E is a linear non-fluorinated hydrocarbon ether of (CH₂CH₂O)₁₋₂CH₂, and E′ is a linear hydrocarbon ether of (CF₂CH₂O(CH₂CH₂O)₁₋₂, and having a molecular weight of about 1000.

R-E-CF₂—O—(CF₂—O—)ₙ(—CF₂—CF₂—O—)ₘ—CF₂-E′-R′

The photoinitiator Darocur 1173 (from Ciba Specialty Chemicals, Basel, Switzerland). The structure of Darocur 1173 is as follows.

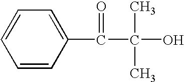

The PFPE diacrylate prepolymer and 1 wt % by weight of Darocur 1173 photoinitiator were mixed and filtered with 0.45 micrometer PTFE filter, forming a PFPE photosensitive composition.

A printing stamp was prepared by pouring the PFPE photosensitive composition onto the developed photoresist pattern of the wafer used as the master, forming a layer having a wet thickness of about 25 micron.

The adhesive surface of the support was then applied to the layer of the PFPE composition away from the master. The PFPE layer was then exposed to UV radiation for 10 min on the 365 nm I-liner, to cure or polymerize the PFPE layer and form a molded stamp. The stamp was then separated by peeling from the master and had a relief surface that corresponded to the pattern in the master.

The modulus of elasticity of the printing stamp was measured using a Hysitron Tribolndenter (Hysitron Inc., Minneapolis Minn.) and determined according to the test method described by Oliver and Pharr in J. Mater. Res. 7, 1564 (1992). The Tribolndenter was equipped with a Berkovich diamond indentor to perform indentations on a sample of the elastomeric stamp. For a stamp, at least two sets of twenty-five indentations to a maximum load of 100 microNewtons were conducted. Any surface effect and interaction with a substrate were minimized by indenting more than ten times the measured surface roughness, but not more than 10% of the total thickness of the sample. Indentations within each set were 10 um apart, and the sets were separated by at least 1 mm. The indentations were made using a 5-2-5 load function in which 5 second to apply the load, 2 second of hold (under load control closed-loop feedback) to reduce the effect of hysteresis/creep, then a 5 second unload. The analysis of the Load/Unload curves for each indentation were performed following the method of Oliver and Pharr to determine the modulus of elasticity. Seventy-five percent of the unload portion of the curve starting from 5% from the top to 20% from the bottom was used for the calculation to determine the modulus of elasticity. The indenter area function that was required for analysis of the nanoindentation data using this method was calculated using a series of indents in fused silica.

The prepared printing stamp had a modulus of elasticity of 40 MegaPascal.

### Application of Surface Modifying Material

The relief surface of the prepared elastomeric stamp was coated with a surface modifying material. The surface modifying material was a light emitting polymer (LEP), COVION® Super NRS-PPV (from Merck). A 0.5 wt % by weight of the Super NRS-PPV solution in toluene was prepared and filtered with a PTFE 1.5 micron filter. The LEP is a poly(para-phenylene vinylene) (co)polymer. The structure of the LEP follows:

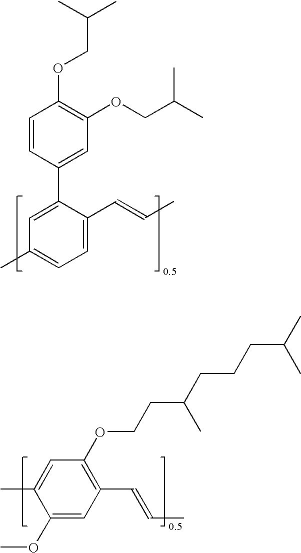

The NRS-PPV solution was spun coated onto the relief surface of the PFPE stamp at 2000 rpm for 60 sec, to coat and form a dry film on the stamp. The relief surface of the stamp included raised portions each having an uppermost planar surface and recessed portions each having a lowermost planar surface. The solution coated the uppermost surface of the raised portions and the lowermost surface of the recessed portions.

Application of Functional Material onto Stamp

A thin layer of silver composition was coated onto the modified surface of the stamp in preparation for printing of the functional material. The functional material used was Silverjet DGP50 (ANP South Korea), which is an alcohol based silver dispersion, composed of silver nano-particles having an average particle size of 50 nm. The as purchased dispersion was diluted by mixing 1.0 grams of the Silverjet DGP50 with 1.0 gram of ethanol and sonicated with a tip sonicator for 5 minutes. The dispersion was twice filtered through a 0.45 micron polytetrafluoroethylene (PTFE) filter. The filtered dispersion was spun for 60 seconds onto the relief surface of the LEP coated PFPE stamp. The dispersion solvents were evaporated during spinning leaving a thin silver film both on the raised and recessed portions of the relief surface of the stamp. The silver film coated on LEP coated PFPE stamp further dried at 65° C. for 1 min on hotplate prior to transfer onto a flexible substrate.

Printing of the Silver Functional Material onto a Flexible Substrate:

Prior to the printing of the silver functional material onto a flexible substrate, an acrylic latex adhesive was spun coated onto the substrate, Melinex® 561 polyester film (5 mil), at 300 rpm for 40 sec, forming a layer. The latex adhesive layer was then annealed at 140° C. for 5 min in a convection oven.

The silver functional material on the elastomeric stamp was printed by contact transfer of the uppermost surface of the raised portions of the relief onto the adhesive side of having the acrylic latex of the substrate. The silver material was transferred by placing the relief surface of the stamp coated with the silver film onto the adhesive coated side of the flexible substrate which was placed on a hot plate at 65° C., and applying gentle pressure to the support side of the stamp. The stamp was separated from the substrate to form a pattern of the silver film on the substrate. The LEP that was coated onto the PFPE stamp surface as the surface modifying material transferred together with the silver. The LEP was washed off the substrate (i.e., the silver pattern) by using toluene. The silver pattern on the flexible substrate was sintered at 140° C. for 3 min in convection oven. The sintering step decreased the sheet resistance of the silver film to 3 ohm/□.

The film thickness of the transfer film was about 200 nm for 50 micron features and about 70 nm for 5 micron lines. The printed silver pattern was a source and drain interdigitated pattern having a resolution of 2 microns. The pattern lines of silver were uniformly clean with smooth edges, and had no breaks. No silver was transferred between the pattern lines.

### Comparative Example 1

Example 1 was repeated except that the elastomeric stamp did not include the surface modifying material.

A thin layer of the silver composition was applied onto the non-modified relief surface of the stamp in preparation for printing of the functional material. The silver solution did not coated well on the non-modified surface of the stamp. The silver solution beaded up on the relief surface of the stamp, and did not spread over the entire surface area. The stamp with the silver material was contacted to the substrate, but the pattern of silver was not reproduced on the substrate.

### Example 2

Example 1 was repeated except that the flexible substrate was not coated with the adhesive, i.e., the flexible substrate did not include the adhesive layer.

The silver functional material on the elastomeric stamp was printed by contact transfer of the uppermost surface of the raised portions of the relief onto the Melinex® 561 polyester film without latex adhesive layer. In order for the transfer to occur, the silver material was transferred by placing the relief surface of the stamp coated with the silver film onto the flexible substrate which was placed on a hot plate at 65° C., and applying gentle pressure to the support side of the stamp. The transfer of the silver material from the stamp was aided by heating the flexible substrate. The stamp was separated from the substrate to form a partial pattern of the silver film on the substrate.

Although the silver pattern did not transfer completely onto the flexible substrate, a substantial portion of the silver pattern did transfer to the substrate. This demonstrates that transfer of a functional material to a substrate that does not have an adhesive layer is possible. It is believed that complete pattern transfer could occur with a different substrate or with the use of a different functional material.

What is claimed is:

1. A method to form a pattern of functional material on a substrate comprising:
a) providing an elastomeric stamp having a relief structure with a raised surface, the stamp having a modulus of elasticity of at least 10 MegaPascal;
b) applying a first composition comprising a surface modifying material to the relief structure that provides uniform application of a second composition;
c) applying the second composition comprising the functional material and a liquid onto the surface modifying material;
d) removing the liquid from the second composition on the relief structure sufficiently to form a film of the functional material on at least the raised surface; and
e) transferring the functional material from the raised surface to the substrate.

2. The method of claim 1 further comprising:
transferring the surface modifying material from the raised surface with the functional material to the substrate.

3. The method of claim 1 wherein the first composition further comprises a liquid.

4. The method of claim 3 wherein the second composition is not soluble in the first composition.

5. The method of claim 3 further comprising removing the liquid from the first composition prior to applying the second composition.

6. The method of claim 1 wherein the surface modifying material is selected from the group consisting of amphiphilic compounds, organo-functional silanes; polyelectrolyte compounds, biologically-active materials, acrylic polymers and their copolymers; methacrylic polymers and their copolymers; vinyl polymers and their copolymers; block copolymers of vinyl polymers and (meth)acrylic polymers, conjugated aromatic polymers and conjugated aromatic copolymers.

7. The method of claim 1 wherein the surface modifying material has a thickness between 0.001 and 2 micrometers on the substrate.

8. The method of claim 1 wherein transferring step comprises contacting the raised surface of the stamp to the substrate with pressure less than about 5 lbs./cm².

9. The method of claim 1 wherein the functional material is incompatible with the elastomeric stamp.

10. The method of claim 1 wherein the liquid of the second composition is incompatible with the elastomeric stamp.

11. The method of claim 1 wherein the functional material is selected from the group consisting of conductive materials, semiconductive materials, dielectric materials, small molecule materials, bio-based materials, and combinations thereof.

12. The method of claim 1 wherein the functional material is selected from the group consisting of electrically active materials, photoactive materials, biologically active materials, insulating materials, planarization materials, barrier materials, and confinement materials, organic dyes, semi-conducting molecules, fluorescent chromophores, phosphorescent chromophores, pharmacologically active compounds, biologically active compounds, compounds having catalytic activites, photoluminescence materials, electroluminescent materials, deoxyribonucleic acids (DNAs), proteins, poly(oligo) peptides, and poly(oligo) saccharides.

13. The method of claim 1 wherein the functional material comprises nanoparticles selected from the group consisting of conductive materials, semi-conductive materials, and dielectric materials.

14. The method of claim 1 wherein the functional material comprises nanoparticles of a conductive material, the method further comprising step e) sintering the nanoparticles on the substrate to form a continuous film of conductive material.

15. The method of claim 14 wherein sintering comprises heating the nanoparticles to temperature up to about 220° C.

16. The method of claim 1 wherein the functional material is a conductive material selected from the group consisting of silver, gold, copper, palladium, indium-tin oxide, and combinations thereof.

17. The method of claim 1 wherein the functional material is a masking material.

18. The method of claim 1 wherein the removing step d) is selected from the group consisting of heating the second composition, blowing a gas stream on the second composition, evaporating, and combinations thereof.

19. The method of claim 1 wherein the elastomeric stamp comprises a layer of a composition selected from the group consisting of silicone polymers; epoxy polymers; polymers of conjugated diolefin hydrocarbons; elastomeric block copolymers of an A-B-A type block copolymer, where A represents a non-elastomeric block and B represents an elastomeric block; acrylate polymers; fluoropolymers, fluorinated compounds capable of polymerization, and combinations thereof.

20. The method of claim 1 further comprising forming the elastomeric stamp from a layer of a photosensitive composition.

21. The method of claim 1 further comprising forming the elastomeric stamp from a layer of a composition comprising a fluorinated compound capable of polymerization by exposure to actinic radiation.

22. The method of claim 21 wherein the fluorinated compound is a perfluoropolyether compound.

23. The method of claim 1 wherein the elastomeric stamp further comprises a support of a flexible film.

24. The method of claim 1 wherein the substrate is selected from the group consisting of plastic, polymeric films, metal, silicon, glass, fabric, paper, and combinations thereof.

25. The method of claim 1 wherein the pattern is transferred onto a layer on the substrate, the layer on the substrate selected from the group consisting of primer layers, adhesion layers, charge injection layers, charge transporting layers, and semiconducting layers.

26. The method of claim 1 wherein the liquid of the second composition comprises one or more compounds selected from the group consisting of organic compounds and aqueous compounds.

27. An element made by the method of claim 1.
